(19) United States
(12) Patent Application Publication
(10) Pub. No.: US 2026/0221374 A1
(43) Pub. Date: Jul. 30, 2026

(54) MULTI-BEAM GENERATING UNIT WITH INCREASED FOCUSING POWER

(71) Applicant: Carl Zeiss MultiSEM GmbH, Oberkochen (DE)

(72) Inventors: Alexander HUEBEL, Schorndorf (DE); Yanko SAROV, Aalen (DE); Wolfgang SINGER, Aalen (DE); Sandra VOGEL, Ulm (DE); Dirk ZEIDLER, Oberkochen (DE)

(21) Appl. No.: 19/575,020

(22) Filed: Mar. 23, 2026

Related U.S. Application Data
(63) Continuation of application No. PCT/EP2024/025270, filed on Sep. 11, 2024.

(30) Foreign Application Priority Data
Sep. 26, 2023 (DE) 10 2023 209 409.6

(51) Int. Cl. H01J 37/12; H01J 37/09; H01J 37/28

(52) U.S. Cl. CPC H01J 37/12; H01J 37/09; H01J 37/28; H01J 2237/0453

(57) ABSTRACT

A multipole array for a multi-beam system that can exhibit better evacuation, less contamination risk, and/or increased manipulation range via a mechanism comprising rounded edges within vacuum gaps, deep pockets formed in conducting material, and/or electrodes within vacuum gaps for generating repelling or attracting forces to charged particles.

### CROSS-REFERENCE TO RELATED APPLICATIONS

The present application is a continuation of, and claims benefit under 35 USC 120 to, international application No. PCT/EP2024/025270, filed Sep. 11, 2024, which claims benefit under 35 USC 119 of German Application No. 10 2023 209 409.6, filed Sep. 26, 2023. The entire disclosure of each of these applications is incorporated by reference herein.

### FIELD

The disclosure relates to multi-beam array element for individually manipulating a plurality of charged particle beamlets and a multi-beam charged particle beam system with such a multi-beam array element.

### BACKGROUND

WO 2005/024881 A2 discloses an electron microscope system which operates with a multiplicity of electron beamlets for parallel scanning an object to be inspected with a bundle of electron beamlets. The bundle of electron beamlets is generated by directing a primary electron beam onto a multi-aperture plate, which has a multiplicity of openings. One portion of the electrons of the electron beam is incident onto the multi-aperture plate and is absorbed there, and another portion of the beam transmits the openings of the multi-aperture plate and thereby in the beam path downstream of each opening an electron beamlet is formed whose cross section is defined by the cross section of the opening. Further multi-aperture plates with a plurality of apertures are provided, wherein at each aperture at least one electrode is provided. Thereby, each one of the plurality of charged particle beamlets can individually be influenced, for example focused or deflected. With for example a single electrode at each aperture, a lens array is provided. With for example four or eight electrodes, a deflector array or stigmator array is provided. With a lens array and further electromagnetic lenses, foci of the electron beamlets are formed onto the surface of the object or sample to be inspected. The primary electron beamlets trigger secondary electrons or backscattered electrons to emanate as secondary electron beamlets from the object, which are collected and imaged onto a detector. Each of the secondary beamlets is incident onto a separate detector element so that the secondary electron intensities detected therewith provide information relating to the sample at the location where the corresponding primary beamlet is incident onto the sample. The bundle of primary beamlets is scanned systematically over the surface of the sample and an electron microscopic image of the sample is generated in the usual way for scanning electron microscopes. The resolution of a scanning electron microscope is limited by the focus diameter of the primary beamlets incident onto the object. Consequently, in multi-beam electron all the beamlets should form the same small focus on the object. Multi-beam deflector or stigmator arrays with at least two electrodes for each aperture have been widely used. They are fabricated for example by MEMS technology. The electrodes are separated by isolating material. Since scattered electrons may stick to surfaces of isolating material and form local surface charges, it is well known from multipole-elements of single beam electron optical systems to form vacuum gaps between electrodes and to reduce the probability that electrons can reach the surfaces of isolating material. For example, various shapes of vacuum gaps between individual electrodes have been proposed. For example, U.S. Pat. No. 5,245,194 shows T-shaped vacuum gaps between eight multi-pole electrodes with surface portions of isolating material only extending—with respect to a corresponding electron beamlet—hidden behind an electrode. U.S. Pat. Nos. 5,401,974 or 6,977,377 show L-shaped vacuum gaps with isolating surface regions hidden behind the electrodes. Other shapes of vacuum gaps, which can reduce the probability of electrons reaching an isolating surface segment are given in U.S. Pat. Nos. 5,041,731, 6,055,719, and 7,554,095. The shapes include T- or L-shaped vacuum gaps, tilted vacuum gaps, curved vacuum gaps, or Labyrinth-shaped vacuum gaps, such that isolating regions are at least partially hidden behind electrodes of the multipole-electrodes such that electrons may not directly reach an isolating surface segment. Furthermore, for example U.S. Pat. No. 7,554,095 provides a charge absorbing electrode in a vacuum gap in line of sight of an electron beam passing the aperture within the multiple electrodes. Thereby, electrons accidentally penetrating a vacuum gap are collected by the charge absorbing electrode, which is connected to ground level. In U.S. Pat. No. 7,276,707 such single-beam solutions have been transferred to array elements for multi-beam charged particle beam system. Array elements for multi-beam charged particle beam systems are typically generated by MEMS technology, by which arbitrary shapes of vacuum gaps and electrodes can easily be manufactured.

DE 10201812 219 A1, US 2017/0125205 A1, US 2016/0336147 A1, DE 102014008083 A1 and DE 68918144 T2 provide technological background information for the present patent application.

I. L. Berry et al., Programmable aperture plate for maskless high-throughput nanolithography, Journal of Vacuum Science and Technology B: Microelectronics and Nanometer Structures Processing, Measurement, and Phenomena 15 (1997), p. 2382-2386, provides certain relevant technological background information.

### SUMMARY

Certain known multipole arrays can have lifetime and reliability issues. These issues can be of particular concern for wafer inspection tasks, where a high reliability with a high up time of a system is typically desired.

The disclosure seeks to provide a multi-pole array element for a multi-beam charged particle beam system that is relatively reliable and has a relatively long lifetime.

Contamination can be a challenge for multi-pole array elements. The disclosure seeks to provide a multi-pole array element for a multi-beam charged particle beam system which is less sensitive to contamination. A reason contamination can occur is related to the difficulty of evacuating multi-pole array elements with a plurality of small apertures. The disclosure seeks to provide a multi-pole array element for a multi-beam charged particle beam system which is suitable for improved high-vacuum operation.

In an aspect, the disclosure provides a multi-pole array for manipulating a plurality of primary charged particle beamlets. The multi-pole array comprises a plurality of first apertures, each one for transmitting one charged particle beamlet from a plurality of primary charged particle beamlets. A multi-pole array comprises a plurality of multi-pole elements, each comprising at least two separate electrodes for manipulation of a charged particle single beamlet. Each of the multi-pole elements is arranged at an aperture. A vacuum gap for separation and isolation of at least two electrodes of a multi-pole element can be improved. A multi-pole array for manipulating a plurality of primary charged particle beamlets can be fabricated by MEMS technology and made of doped Silicon or Poly-Silicon as conducting material, and for example Silicon Dioxide as isolating material. A multi-pole array can further comprise metal coatings, for example comprising Gold, Aluminum, Copper, or Tungsten.

At each aperture of a multi-pole array, at least a first electrode and a second electrode can be arranged. Each electrode can be individually connected to a control unit for individual control of each primary charged particle beamlet. With the at least two electrodes, a beamlet can be deflected. Multipole arrays can comprise more electrodes at each aperture, for example six, eight, twelve, or even more electrodes. Thereby, each beamlet can be shaped, for example an astigmatism can be compensated, of a focusing power can be achieved. Each electrode has a radial thickness T1 and an inner surface within an aperture. Between the apertures, a multi-pole array can comprise a conducting material, which can serve as a shield of the electrostatic fields and is reduces a crosstalk between different multipole elements at different apertures. These structure or structures formed from the conducting material are also called shielding electrodes. The plurality of electrodes of the multi-pole elements, comprising at least two electrodes at each aperture, are further connected via an isolating material to the multi-pole array, for example to the conducting material forming the shielding electrodes. For example, the at least first electrode and a second electrode are isolated from conducting material or a shielding electrode by ring segments of an insulating material between the electrodes and a shielding electrode. Between the first and second electrode, a vacuum gap with two side surfaces is formed with a width W and depth T3. Depth T3 is larger than the radial thickness T1 of an electrode and depth T3. In an example, the two side surfaces are parallel to each other.

In an example, the depth T3 is at least equal to or exceeds a depth T2 of the ring segments of insulating material with T3>=T2. Thereby, an open surface of an insulating material is within a side surface of a vacuum gap and a cross section of the open surface of the insulating material with respect to scattered charged particles can be reduced. In an example, the depth T3 exceeds a depth T2 such that pockets are formed within the conducting material of a shielding electrode. Thereby, contamination particles can be collected inside the pockets of conducting material and may not cause sticking charges to the open surface of the insulating material.

In an example, the width W is smaller than 4 μm, for example 2 μm or less, for example 1.6 μm and the aspect ratio AR=T1/W is larger than 8:1, for example 10:1. Thereby, any parasitic fields generated by charges deep within a vacuum gap, for example by sticking charged to the open surface of the insulating material, may not interfere with the electrostatic field generated by the electrodes of the multi-pole element inside an aperture.

In an example, a tangent to the side surface of the vacuum gap is inclined with respect to a radius vector to a center of the corresponding aperture by an inclination angle J with J>15°, for example 20° or 30° or even 45°. Thereby, a probability that scattered charged particle reach an open surface of insulating material can be reduced.

In an example, an intersection between the inner side surface of the first electrode with an aperture and a side surface of a vacuum gap form at the intersection a rounded, cylindrical edge segment. Thereby, large field gradients at sharp edges or intersections of two surfaces are avoided and large field gradients can be avoided. Large field gradients may attract charged contamination particles, which may stick to the sharp edges and build up regions of possible sparks. With rounded, cylindrical edge segment with a radius R exceeding 1 μm, for example R=2 μm or R=3 μm, large field gradient at sharp edges are avoided, contamination growth and the risk of sparks can be reduced.

In an example, a side surface of the vacuum gap comprises a rounded surface segment for avoiding large field gradients at sharp edges within the vacuum gap. For example, a vacuum gap has a cross section in shape of an “s” or a rounded chevron- or “c”-shape. With the “s” or “c”-shape, a probability that scattered charged particle reach an open surface of insulating material can be reduced.

In an example, the multi-pole array further comprises a voltage supply for providing a voltage Ub to the conducting material of for example the shielding electrodes. Thereby, a voltage can be provided to for example the shielding electrodes, and charged particles can be attracted into or repelled from entering a vacuum gap. Thereby, for example, charged particles can be attracted into the pockets formed within the shielding electrodes.

In an example, a multi-pole array comprises additional electrodes made from conducting material, arranged within the vacuum gaps in direction of a line of sight LoW with charged particles transmitting the corresponding aperture, for example in direction of a line of sight LoW to a center of the corresponding aperture. These electrodes may serve as lightning conductors for the collection of currents from sparks generated within a vacuum gap. These electrodes may further be connected to the voltage supply for providing the voltage Ub and may serve as attracting or repelling electrodes. For example, the additional electrodes are provided with a negative voltage for preventing scattered electrons from entering deep into a vacuum gap. Thereby, positive charged contamination particles are attracted to the additional electrodes and may not stick to other surface segments of the vacuum gaps. Thereby, a probability that scattered charged particle reach an open surface of insulating material is reduced. The voltage Ub can for example also be applied during an evacuation, and a pulsed or alternating voltage can be applied. Thereby, an evacuation of residual gases and contamination particles can be improved. In an example, the additional electrode is formed by a thin wire or wire grid.

In an example, the multi-pole array comprises a conducting cover layer at a first side of incidence of the plurality of primary charged particles. The conducting cover layer can comprise the plurality of apertures and at each aperture a plunging extension extending in propagation direction into an aperture. Thereby, at each aperture, a ring-shaped first radial vacuum gap can be formed between the plunging extension of the conducting cover layer and each electrode of an aperture. Thereby, an insulating material for isolating the electrodes from the conducting cover layer can be shielded by the plunging extension and a probability that scattered charged particle reach an open surface of insulating material can be reduced.

In an example, each of the electrodes further comprises a plunging extension extending in propagation direction of a transmitting beamlet. The plunging extensions of the electrodes can form a second radial vacuum gap with a bottom layer formed of conducting material downstream of the electrodes. The plunging extensions of the electrodes can cover an insulating material which serves for isolating the electrodes from conducting material downstream of the electrodes. Thereby, the electrodes can be embedded—in propagation direction of the transmitting charged particles—within a conducting cover layer and conducting bottom layer. In an example, at least one round shaped ring segment is provided at the first or second radial vacuum gap for avoiding large field gradients at sharp edges of a radial vacuum gap.

In an example, a multi-pole array comprises a plurality of second or vacuum apertures. Each of the vacuum apertures can be connected from the rear end to a vacuum gap. Thereby, an evacuation of narrow vacuum gaps can be improved. In an example, a multi-pole array for manipulating a plurality of primary charged particle beamlets comprises a plurality of first apertures, each one for transmitting one of the plurality of primary charged particle beamlets and at least a first electrode and a second electrode arranged at each aperture. Each of the electrodes can be connected to a control unit for individual control of each of a plurality of charged particle beamlets. Each of the first and second electrodes can have an inner surface within an aperture and can comprise a layer of isolating material on a side opposite to the inner surface, the layer of isolating material being covered by conducting material connected to a voltage supply for providing a voltage Ub or ground level. The cover of conducting material thereby can form a shielding electrode. Between the at least first and second electrodes, a vacuum gap with side surfaces can be formed. The multi-pole array can comprise a first outer layer, covering the electrodes from a direction of the incident primary beamlets, comprising the plurality of first apertures, and further comprising a plurality of second or vacuum apertures, which can provide improved evaporation of a vacuum space between the electrodes of different apertures. In an example, the voltage supply is configured to provide a pulsed voltage Ub to the shielding electrode during evacuation, which can result in improved evacuation of a vacuum gap.

The disclosure can provide a vacuum separation of electrodes of a multi-pole element which can have improved lifetime and increased operational range is provided. With vacuum gaps of widths below few μm, limited by the small dimensions of the apertures of the multi-pole array of about 40 μm to 80 μm, at least one of an effect can be achieved, the effects comprising:
a reduction of large field gradients at sharp edges and thereby a reduction of contamination growth and the risk of sparks,
an improvement to an evacuation of narrow vacuum gaps,
a collection of charged particles, including contamination particles, in pockets of conducting material,
a reduction of an impact of parasitic fields generated by charged particles inside narrow vacuum gaps on the multi-pole field generated within an aperture,
a reduction of a cross-section of an open surface of an isolating material with respect to scattered charged particles,
a reduction of a risk that scattered charged particles hit a cross-section of an open surface of an isolating material.

The examples and embodiments according to the disclosure are applicable to any multi-pole array, for example a multi-pole array within a primary beamlet generating unit, a corrector for telecentricity, or within a secondary electron beam path.

It will be understood that the disclosure is not limited to the embodiments and examples but comprises also combinations and variations of the embodiments and examples.

### BRIEF DESCRIPTION OF THE DRAWINGS

Embodiments of the present disclosure will be explained in more detail with reference to drawings, in which:

FIG. 1 is a schematic sectional view of a multi-beam charged particle system;

FIG. 2 illustrates parts of a multi-beam charged particle system;

FIG. 3 shows an example of a filter plate;

FIG. 4 shows an example of a multi-beam forming unit;

FIG. 5 shows an example of a multi-pole array;

FIGS. 6A-6C show some examples of prior art multi-pole arrays;

FIGS. 7A-7B show examples of a multipole array;

FIGS. 8A-8B illustrate a failure mechanism of a prior art multi-pole array;

FIGS. 9A-9D show examples of a multipole array;

FIGS. 10A-10C show examples of a multipole array;

FIG. 11 shows a cross-section of a multipole array; and

FIGS. 12A-12B show an example of a multipole array.

### DESCRIPTION OF EXEMPLARY EMBODIMENTS

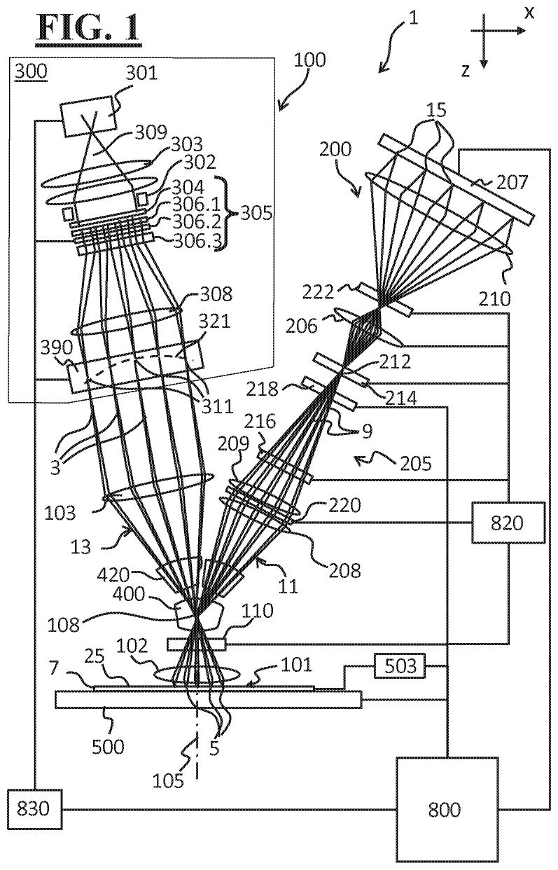

In the exemplary embodiments of the disclosure described below, components similar in function and structure are indicated as far as possible by similar or identical reference numerals. The multi-beam raster units of the examples are described in the illumination beam path with charged particles propagating in positive z-direction with the z-direction pointing downwards. However, multi-beam raster units can also be applied in the imaging beam path, with secondary charged particle beamlets propagating in negative z-direction in the coordinate system of FIG. 1. Still, the sequence of multi-aperture plates is arranged in sequence in the propagating direction of the transmitting charged particle beam or beamlets. With beam entrance side or upper side is understood the first surface or side of an element in the direction of the transmitting charged particle beam or beamlets, with bottom side or beam exiting side is understood the last surface or side of an element in the direction of the transmitting charged particle beam or beamlets.

Some array elements, for example the plurality of primary charged particle beamlets, are identified by the reference number. Depending on the context, the same reference number may also identify a single element out or the array elements. Each primary charged particle beamlet (3.1, 3.2, 3.3, 3.4) is one of the plurality of primary charged particle beamlets (3). It will be clear from the context, whether a single element of an array of elements is meant.

The schematic representation of FIG. 1 illustrates basic features and functions of a multi-beam charged-particle system 1 according to the embodiments of the disclosure. It is to be noted that the symbols used in the figure have been chosen to symbolize their respective functionality. The type of system shown is that of a multi-beam scanning electron microscope (MSEM or Multi-SEM) using a plurality of primary electron beamlets 3 for generating a plurality of primary charged particle beam spots 5 on a surface 25 of an object 7, such as a wafer located with a top surface 25 in an object plane 101 of an objective lens 102. For simplicity, only five primary charged particle beamlets 3 and five primary charged particle beam spots 5 are shown. The features and functions of multi-beamlet charged-particle system 1 can be implemented using electrons or other types of primary charged particles such as ions and in particular Helium ions. Further details of the microscope system 1 are provided WO 2022 262970 A1, which is hereby fully incorporated by reference.

The system 1 comprises an object irradiation unit 100 and a detection unit 200 and a beam splitter unit 400 for separating the secondary charged-particle beam path 11 from the primary charged-particle beam path 13. Object irradiation unit 100 comprises a charged-particle multi-beam generator 300 for generating the plurality of primary charged-particle beamlets 3 and is adapted to focus the plurality of primary charged-particle beamlets 3 in the object plane 101, in which the surface 25 of a wafer 7 is positioned by a sample stage 500.

The primary beam generator 300 produces a plurality of primary charged particle beamlet spots 311 in an intermediate image surface 321, which is typically a spherically curved surface. According to the embodiments of the disclosure, the intermediate image plane 321 is further tilted to compensate a tilt induced by the off-axis symmetry of the object irradiation unit 100. The positions of the plurality of focus points (311) of the plurality of primary charged particle beamlets (3) is adjusted in the intermediate image surface (321) by a multi-beam generating unit (305) to pre-compensate field curvature and image plane tilt of optical elements of the object irradiation unit (100) downstream of the multi-beam generating unit 305. The orientation of the image plane tilt and the amount of field curvature of intermediate image surface 321 is adjusted according to the driving parameters of the object irradiation unit 100, for example on the focusing power of the objective lens 102 or the electrostatic field generated between the objective lens 102 and the wafer surface 25 by the voltage supplied by the sample voltage supply (503), which both are the main sources for field curvature and rotation of the tilted image plane. More details about the intermediate image plane curvature and tilt are described in German patent DE 102021200799 B3, which is incorporated herein by reference.

The primary beamlet generator 300 comprises a source 301 of primary charged particles, for example electrons. The primary charged particle source 301 emits a diverging primary charged particle beam, which is collimated by at least one collimating lens 303 to form a collimated or parallel primary charged particle beam 309. The collimating lens 303 is usually consisting of one or more electrostatic or magnetic lenses, or by a combination of electrostatic and magnetic lenses. The primary beamlet generator 300 further comprises a deflector 302 for adjusting the angle of the collimated or parallel primary charged particle beam 309. The collimated primary charged particle beam 309 is incident on the primary multi-beam forming unit 305. The multi-beam forming unit 305 basically comprises a first multi-aperture plate or filter plate 304 illuminated by the collimated primary charged particle beam 309. The first multi-aperture plate or filter plate 304 comprises a plurality of apertures in a raster configuration for generation of the plurality of primary charged particle beamlets 3, which are generated by transmission of the collimated primary charged particle beam 309 through the plurality of apertures. The multi-beamlet forming unit 305 comprises at least two of further multi-aperture plates 306.1 and 306.2, which are located, with respect to the direction of movement of the electrons in beam 309, downstream of the first multi-aperture or filter plate 304. For example, a second multi-aperture plate 306.1 has the function of a micro lens array, comprising a plurality of ring electrodes, each ring electrode set to an individually defined potential so that the focus positions of the plurality of primary beamlets 3 are independently adjusted in the intermediate image surface 321. A third multi-aperture plate 306.2 comprises for example four or eight of electrostatic elements for each of the plurality of apertures, for example to deflect each of the plurality of beamlets individually. The third multi-aperture plate 306.2 is thus forming a multipole array element. In an example, multi-beamlet forming unit 305 is configured with further multi-aperture plate (306.3), which can be configured as a further multipole array element. Together with the field lens 308, the plurality of primary charged particle beamlets 3 is focused in or in proximity of the intermediate image surface 321.

In or in proximity of the intermediate image surface 321, a beam steering multi aperture plate 390 can be arranged with a plurality of apertures with electrostatic elements, for example multipole elements such as deflectors, to manipulate individually the propagation direction of each of the plurality of charged particle beamlets 3. The apertures of the beam steering multi aperture plate 390 are configured with larger diameter to allow the passage of the plurality of primary charged particle beamlets 3 even in case the focus spots 311 of the primary charged particle beamlets 3 are located on the curved intermediate image surface 321. The primary charged-particle source 301, each of the active multi-aperture plates 306.1, 306.2, 306.3 and the beam steering multi aperture plate 390 are controlled by primary beamlet control module 830, which is connected to control unit 800.

The plurality of focus points of primary charged particle beamlets 3 passing the intermediate image surface 321 is imaged by field lens group 103 and objective lens 102 into the image or object plane 101, in which the surface 25 of the wafer 7 is positioned. A decelerating electrostatic field is generated between the objective lens 102 and the wafer surface by application of a voltage to the wafer by the sample voltage supply (503). The object irradiation system 100 further comprises a collective multi-beam raster scanner 110 in proximity of a first beam cross over 108 by which the plurality of charged particle beamlets 3 can be deflected in a direction perpendicular to the propagation direction of the charged particle beamlets. The propagation direction of the primary beamlets throughout the examples is in positive z-direction, which is consistent with the optical axis 105 at the object plane 101. Objective lens 102 and collective multi-beam raster scanner 110 are centered at an optical axis 105 of the multi-beam charged-particle system 1, which is perpendicular to wafer surface 25. The plurality of primary charged particle beamlets 3, forming the plurality of beam spots 5 arranged in a raster configuration, is scanned synchronously over the wafer surface 25. In an example, the raster configuration of the focus spots 5 of the plurality of N primary charged particle 3 is a hexagonal raster of about one hundred or more primary charged particle beamlets 3, for example N=91, N=100, or N approximately 300 or more beamlets. The primary beam spots 5 have a distance about 6 μm to 15 μm and a diameter of below 5 nm, for example 3 nm, 2 nm or even below. In an example, the beam spot size is about 2.5 nm, and the distance between two adjacent beam spots is 8 μm. At each scan position of each of the plurality of primary beam spots 5, a plurality of secondary electrons is generated, respectively, forming the plurality of secondary electron beamlets 9 in the same raster configuration as the primary beam spots 5. The intensity of secondary charged particle beamlets 9 generated at each beam spot 5 depends on the intensity of the impinging primary charged particle beamlet 3, illuminating the corresponding spot 5, the material composition and topography of the object 7 under the beam spot 5, and the charging condition of the sample at the beam spot 5. Secondary charged particle beamlets 9 are accelerated by the electrostatic field generated by the sample charging unit 503 between the sample 7 and the objective lens 102. The plurality of secondary charged particle beamlets 9 are accelerated by the electrostatic field between objective lens 102 and wafer surface 25 and are collected by objective lens 102 and pass the first collective multi-beam raster scanner 110 in opposite direction to the primary beamlets 3. The plurality of secondary beamlets 9 is scanning deflected by the first collective multi-beam raster scanner 110. The plurality of secondary charged particle beamlets 9 is then guided by beam splitter unit 400 to follow the secondary beam path 11 of the detection unit 200. The plurality of secondary electron beamlets 9 is travelling in opposite direction from the primary charged particle beamlets 3, and the beam splitter unit 400 is configured to separate the secondary beam path 11 from the primary beam path 13 usually via magnetic fields or a combination of magnetic and electrostatic fields. Optionally, additional magnetic correction elements 420 are present in the primary or in the secondary beam paths.

Detection unit 200 images the secondary electron beamlets 9 onto the image sensor 207 to form there a plurality of secondary charged particle image spots 15. The detector or image sensor 207 comprises a plurality of detector pixels or individual detectors. For each of the plurality of secondary charged particle beam spots 15, the intensity is detected separately, and the material composition of the wafer surface 25 is detected with high resolution for a large image patch of the wafer with high throughput. For example, with a raster of 10×10 beamlets with 8 μm pitch, an image patch of approximately 88 μm×88 μm is generated with one image scan with collective multi-beam raster scanner 110, with an image resolution of for example 2 nm or below. The image patch is sampled with half of the beam spot size, thus with a pixel number of 8000 pixels per image line for each beamlet, such that the image patch generated by 100 beamlets comprises 6.4 gigapixel. The digital image data is collected by control unit 800. Details of the digital image data collection and processing, using for example parallel processing, are described in international patent application WO 2020151904 A2 and in U.S. Pat. No. 9,536,702, which are hereby incorporated by reference.

Projection system 205 of the detection unit 200 further comprises at least a second collective raster scanner 222, which is connected to scanning and imaging control unit 820. Control units 800 and imaging control unit 820 are configured to compensate a residual difference in position of the plurality of focus points 15 of the plurality of secondary electron beamlets 9, such that the positions of the plurality secondary electron focus spots 15 are kept constant at image sensor 207.

The projection system 205 of detection unit 200 comprises further electrostatic or magnetic lenses 208, 209, 210 and a second cross over 212 of the plurality of secondary electron beamlets 9, in which an aperture filter 214 is located. Imaging control unit 820 is further connected to at least one electrostatic lens 206 and a third deflection unit 218. The projection system 205 can further comprise at least a first multi-aperture corrector 220, with apertures and electrodes for individual influencing each of the plurality of secondary electron beamlets 9, and an optional further active element 216, connected to control unit 800 or imaging control unit 820.

The image sensor 207 is configured by an array of sensing areas in a pattern compatible to the raster arrangement of the secondary electron beamlets 9 focused by the projecting lens 205 onto the image sensor 207. This enables a detection of each individual secondary electron beamlet independent from the other secondary electron beamlets incident on the image sensor 207. The image sensor 207 illustrated in FIG. 1 can be an electron sensitive detector array such as a CMOS or a CCD sensor. Such an electron sensitive detector array can comprise an electron to photon conversion unit, such as a scintillator element or an array of scintillator elements. In another embodiment, the image sensor 207 can be configured as electron to photon conversion unit or scintillator plate arranged in the focal plane of the plurality of secondary electron particle image spots 15. In this embodiment, the image sensor 207 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702, which is cited above and incorporated by reference. In an example, the relay optical system further comprises a beam splitter for splitting and guiding the light to a first, slow light detector and a second, fast light detector. The second, fast light detector is configured for example by an array of photodiodes, such as avalanche photodiodes, which are fast enough to resolve the image signal of the plurality of secondary electron beamlets 9 according to the scanning speed of the plurality of primary charged particle beamlets 3. The first, slow light detector can be a CMOS or CCD sensor, providing a high-resolution sensor data signal for monitoring the focus spots 15 or the plurality of secondary electron beamlets 9 and for control of the operation of the multi-beam charged particle microscope 1.

During an acquisition of an image patch by scanning the plurality of primary charged particle beamlets 3, it is generally desirable that the stage 500 is not moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

According to an embodiment of the disclosure, a plurality of electrical signals is created and converted in digital image data and processed by control unit 800. During an image scan, the control unit 800 is configured to trigger the image sensor 207 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

A multi-beam generating unit 305 is for example explained in US 2019/0259575, and in U.S. Pat. No. 10,741,355 B1, both hereby incorporated by reference. Further details of a multi-beam generating unit 305, which is insensitive to fabrication errors and scattering are disclosed in WO 2021180365 A1, which is hereby incorporated by reference.

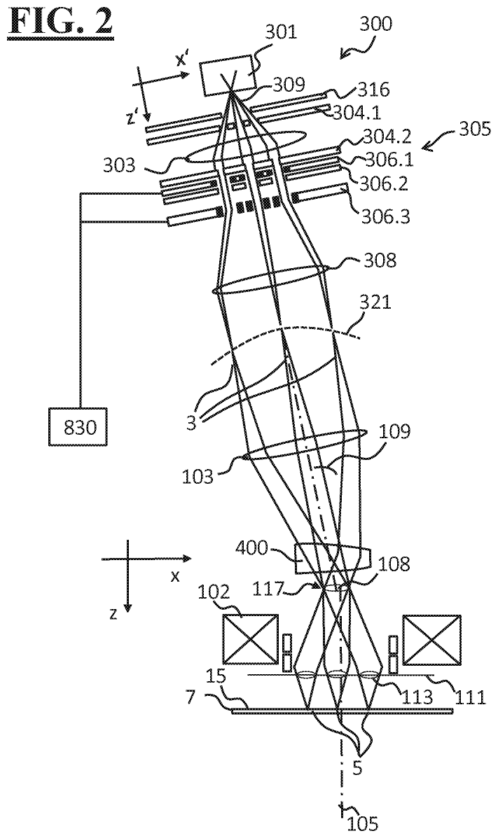

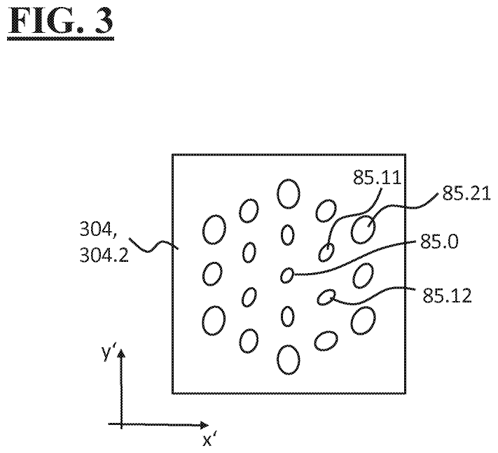

FIG. 2 illustrates a further example of an embodiment of the disclosure. Same reference numbers of FIG. 1 are used and reference is also made to FIG. 1. The example of FIG. 2 comprises a first aperture plate 316 and a first filter plate 304.1, by which a primary electron beam 309 is filtered. The prefiltered electron beam is collimated by condenser 303 and incident on a second filter plate 304.2, by which the primary beamlets are finally shaped. The first filter plate 304.1 helps to reduce an electron current absorbed by the second filter plate 304.2. FIG. 2 further illustrates the example of a tilt angle 109 within the primary beam path 11, introduced by the beam divider 400. According to the tilt angle 109, the axis z′ upstream of the beam divider is inclined by tilt angle 109 with respect to the z-axis corresponding to the optical axis 105 at wafer level. For identical imaging properties, each primary electron beamlet is to be circular and identical. Identical means that also the pupil distribution 117 of each electron beamlet 3 in the pupil or cross over plane 108 is to be identical. This is equivalent to—for each beamlet 3—equal far field distributions 113 in a plane 111 parallel to the image plane 101 (see FIG. 1). To achieve equal and circular far field distributions 113 or equal and circular pupil distributions 117, respectively, the beam forming apertures in the filter plate 304 are configured to pre compensate the geometrical effect of the beam tilt angle 309. FIG. 3 shows an example with a reduced number of beamlets 3. Each beam shaping aperture 85.0 to 85.ij of the filter plate 304 or 304.2 shows a slightly different elliptical shape. With different size and different elliptical shape, field curvature, image plane tilt and geometrical effects due to tilt angle 109 are pre-compensated.

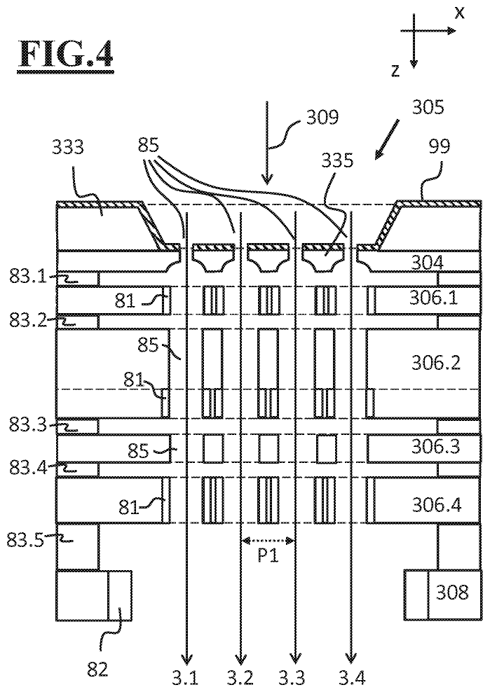

FIG. 4 shows a cross section of an example of a multi-beam generating unit 305. The example of FIG. 4 comprises an inner zone 335 with the membranes of the multi-aperture plates 304 and 306 of the multi-beam generating unit 305. A stack of multi-aperture plates further comprises a support zone 333 to support the thin membrane zone and to provide mechanical stability. The multi-beam generating unit 305 comprises in z-direction of the propagating electrons a sequence of five multi-aperture plates 304 and 306.1 to 306.4, and a global condenser lens 308. Each multi aperture plate 304 and 306.1 to 306.4 comprise a plurality of apertures 85, spaced at the same lateral distance P1 of about 70 μm to 100 μm in each plate and each plate aligned such that a plurality of primary charged particle beamlets 3 is generated and shaped. In the example of FIG. 4, the plurality of multi-aperture plates 304 and 306.1 to 306.4 and global field lens 308 with electrode 82 are spaced by spacers 83.1 to 83.4 and spacer 83.5. However, other configurations, for example without spacers 83.1 o 83.4 are possible as well. The multi-beam generating unit 305 is illustrated in cross section (x, z) with only four apertures 85 in each multi-aperture plate in the inner membrane zone 335. As discussed above, the number of beamlets 3 and corresponding number of apertures 85 can be much larger.

The multi-beam generating unit 305 comprises two multi-pole or multi-stigmator arrays 306.1 and 306.4. Multi-pole or multi-stigmator arrays are further labelled by reference number 316. For example, multi-pole array 306.4 serves as a multi-deflector array for adjusting a beam pitch in the intermediate image plane 321 (see FIG. 2). Each of the multi-pole arrays 306.1 and 306.4 comprises a plurality of four or more electrodes 81, for example eight electrodes, for each of the plurality of apertures 85. During use, different voltages for example in the range between −20V to +20V can be provided individually to each of the electrodes 81, and thereby each beamlet 3.1 to 3.4 can be influenced individually. For example, with an antisymmetric voltage difference, each beamlet 3.1 to 3.4 can be deflected in a direction to adjust a pitch or pre-compensate a distortion aberration of the illumination unit 100.

With the optional further global field lens 308, attached with spacer 86 to the stack of multi-aperture plates 306, each of the plurality of primary charged particle beamlets 3 including the beamlets 3.1 to 3.4 is focused during use into the curved and tilted intermediate image plane 321 to form focus stigmatically corrected spots.

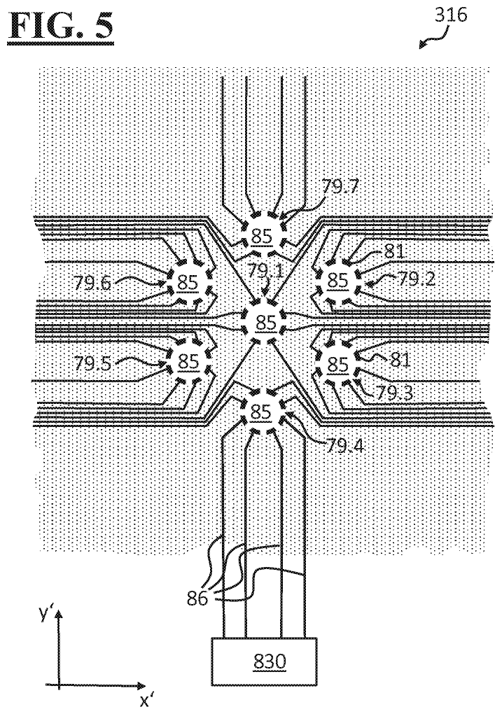

A multi-beam charged particle beam system 1 therefore comprises at least one multipole array element (306.1, 306.2, 306.3 or 306.4; 316). FIG. 5 illustrates schematically a top view of a multi-pole array 316 with eight electrodes 81 for each aperture 85. For better illustration, only seven apertures 85 are shown. Eight electrodes 81 at each aperture form a multipole element 79, seven multipole elements 79.1 to 79.7 are shown. The arrangement of FIG. 5 shows a hexagonal symmetry, but other shapes such as a cartesian raster are possible as well. The several electrodes 81 at each aperture are isolated from each other. Each of the plurality of multi-pole electrodes 81 is connected to a control unit 830 by wiring interconnections 86 configured for individually influencing each primary beamlet during use. During use, a plurality of low voltages in the range of −20V to 20V is applied to the plurality of electrodes.

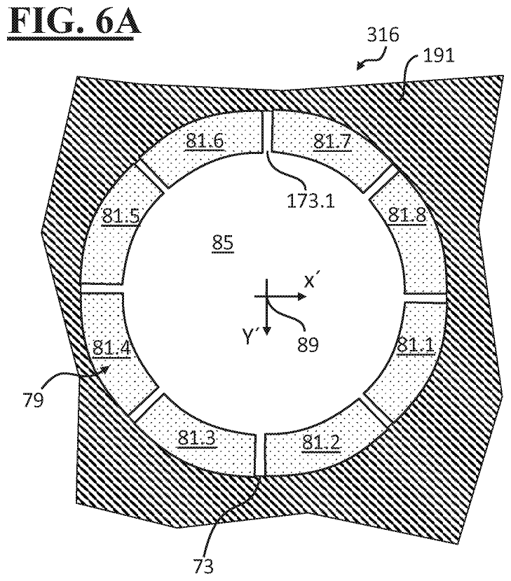

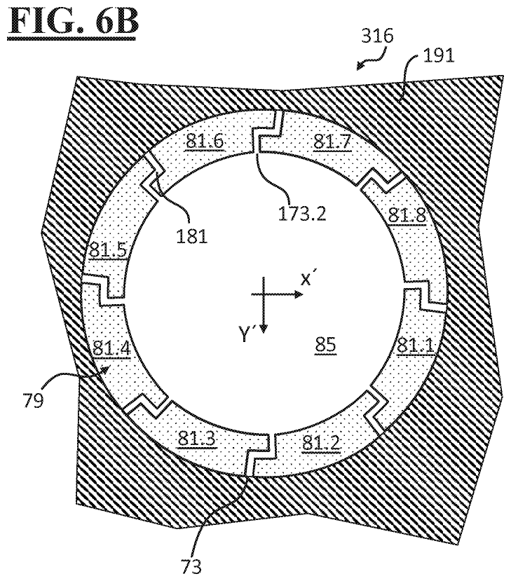

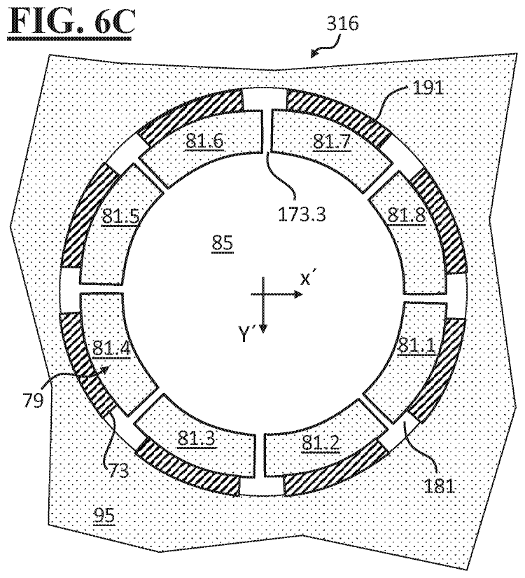

FIG. 6A illustrates a multipole electrode 81 with a ring of electrodes 81.1 to 81.8 of a multipole element 79 of a multipole array 316 according to the prior art. The ring of electrodes 81.1 to 81.8 in the circumference of a corresponding aperture 85 has typically a radial extension between 2 μm to 10 μm. Between each electrode 81.1 to 81.8 an isolation vacuum gap or recession 173.1 is formed. The electrodes 81.1 to 81.8 are further embedded in isolating material 191. The electrodes are further connected by electrical interconnections to the control unit 830 (not shown). Vacuum gaps 173.1 are extending in radial direction from a center 89 of an aperture 85. One issue of this solution are the open surface regions 73 of the isolating material 191 inside the vacuum gaps. Scattered electrons may reach surface region 73 and stick to the isolating material 191, thereby inducing unwanted effects to the electrostatic field generated by the multipole array 316 during use. A first attempt to solve this issue was the introduction of labyrinth-shaped vacuum gaps 173.2, as illustrated in FIG. 6B. With labyrinth-shaped vacuum gaps 173.2, open surfaces 73 of isolation material can effectively be shielded by conducting electrodes 81.1 to 81.8 and a probability for scattered electrons to reach surfaces 73 of isolating material 191 is reduced. FIG. 6C shows another multipole element 79 according to the prior art with T-shaped vacuum gaps 173.3 between electrodes 81.1 to 81.8 embedded in ring segments of isolating material 191, and altogether embedded in conducting material 95. A conducting material 95 may be connected to ground. A conducting material has the property to shield electrical fields generated by the electrodes 81.1 to 81.8 of each multi-pole element 79 of the multi-pole array 316 and has generally been used to suppress cross-talk between individual multi-pole elements of the multi-pole array 316.

Each aperture 85 has typically a diameter D about 40 μm<=D<=70 μm; each vacuum gap thus has a width W of few μm only, for example 5 μm, 4 μm, or 3 μm, or even less. Those narrow labyrinth-shaped vacuum gaps 173.2 or T-shaped vacuum gaps 173.3 with corners or edges 181 (see FIGS. 6B and 6C) are more difficult for evacuation and it is more difficult to reach certain desired high vacuum properties of charged particle beam systems. Narrow vacuum gaps 173.2 or 173.3 with corners or edges 181 generally involve longer times to reach low vacuum pressure or 10E-6 Torr or below, if this is possible at all within the vacuum gaps 173.

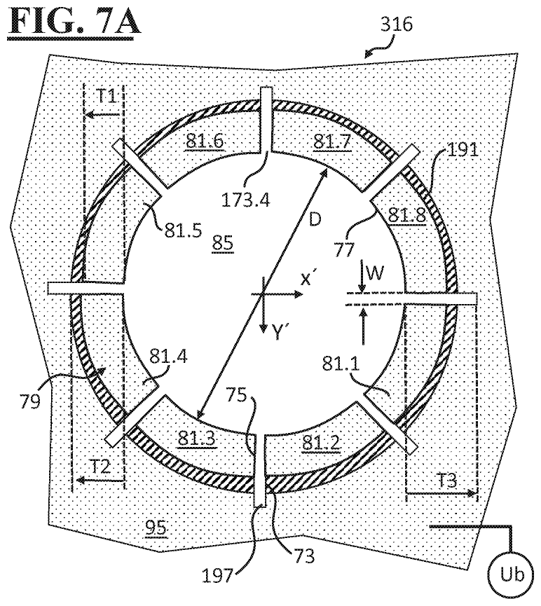

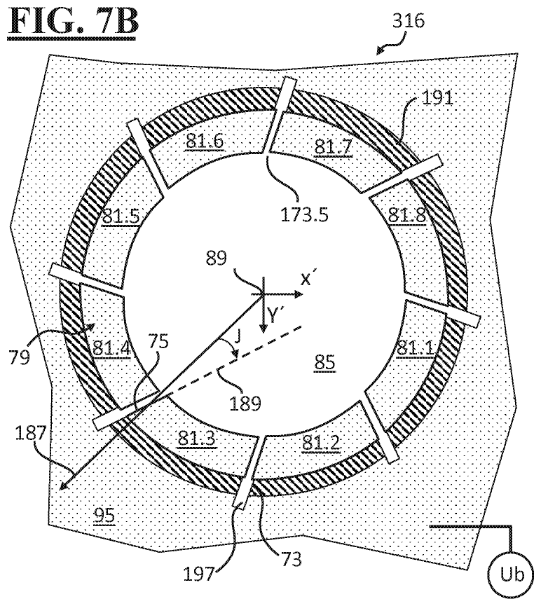

According to a first example of a multipole array 316, it is therefore advantageous to use vacuum gaps 173.4 without corners or edges 181 inside a vacuum gap 173. An example of a solution using deep vacuum gaps 173.4 is illustrated in FIG. 7A. The multipole electrodes 81.1 to 81.8 are arranged at an aperture 85 of a multipole array element 316 and are embedded in ring segments of an isolating material 191, which again is embedded in conducting material 95, such as doped Silicon or Poly-Silicon. Conducting material 95 therefore forms a shielding electrode. Deep vacuum gaps or trenches 173.4 are formed with a depth T3 reaching behind the depth T2 of the isolating material 191 and into the conducting material 95 has the function of a shielding electrode. The open surface regions 73 of isolating material 191 are at the sidewalls 75 of the vacuum gaps 173.4 and thus of reduced cross sections with the line of sight of an electron beamlet 3 passing the aperture 85. Thereby, a probability that scattered electrons reach the open surface regions 73 of isolating material 191 is reduced. In an example, furthermore a thickness T1 of the ring of electrodes is increased and about 10 μm, 15 μm or 20 μm. Generally, a larger thickness of the electrodes in radial direction increases the volume and therefore the capacity of each electrode. A larger capacity provides more stability with respect to fluctuating charges or a charge diffusion.

With increased depth of the trenches 173.4, and a width W of about 3 μm or less, for example 2 μm or 1.6 μm, an aspect ratio AR of depth T1 to diameter W can reach AR=8:1 or AR=10:1 or more. Thereby, a probability that scattered electrons reach the open surface regions 73 of isolating material 191 is further reduced. With such a deep trench 173.4 with aspect ratio AR=T1:W of AR>=8:1, for example, a positive voltage Ub can be applied to the conducting material 95 without any disturbing impact to the multipole field generated by the multipole electrodes 81.1 to 81.8 within the aperture 85. In addition, conducting material 95 still forms a shielding electrode between electrodes of different multipole elements 79 of the multipole array 316. Thereby, any electron or charged particle with negative charge reaching the depth between T2 and T1 is accelerated to the conducting material 95 and the probability that scattered electrons reach the open surface regions 73 of isolating material 191 is further reduced. Furthermore, the deep trenches 173.4 reaching into the conducting material 95 comprises pockets 197 within the conducting material 95, which can serve as collector of contamination particles. By collecting contamination particles in the pockets 197, a lifetime of a multipole-array element 316 is increased. On the other hand, for example a contamination particle of positive charge is repelled by the positive voltage Ub provided to conducting material 95 and may not enter deep into the trenches 173.4 and is thus more easily evacuated through the apertures 85. For example, during an evacuation, voltage pulses can be provided to the conducting material 95 to push charged contamination particles out of the trenches 173.4.

According to a further example, the deep vacuum gaps or trenches can further be provided at a tilt angle J between a tangent to a side surface 75 of the deep trench 173.5 and a radius vector 187 to an aperture center 89. Such an example is illustrated in FIG. 7B. With the tilt angle J, a probability that scattered electrons reach the open surface segments 73 of isolating material 191 is even further reduced. A tilt angle J can be selected to exceed 15°, 20°, 30° or even more, for example 45°. With larger tilt angle J exceeding 30°, a probability of scattered electrons to reach the open surface segments 73 of isolating material 191 is even further reduced. While the tilt angles J are equal and with same direction in FIG. 7B, it is desirable for this to not be the case. Different tilt angles J between adjacent electrodes 81.1 to 81.8 are possible as well, and different orientation of the vacuum gaps 173.5 with different positive or negative angles J of each vacuum gap 173.5. It should be noted that the multipole array element 316 according to any example is generally not limited to only eight electrodes 81.1 to 81.8 at each aperture 85, but the number of electrodes 81 can be any number larger than one, such that at least two adjacent electrodes 81.1 and 81.2 are separated from each other by an isolating gap 173.

A further problem of narrow vacuum gaps to be addressed are the high field gradients within narrow vacuum gaps 173. Typically, large field gradients limit the voltage range applied to multipole elements 79. For example, typical maximum voltage differences allowed for adjacent electrodes are in a range below 20V, and electrical sparks arise at higher voltages. One particular reason for sparks is residual gas pressure after evacuation or a contamination particle within the vacuum. It has turned out that sparks especially arise at corners or edges of vacuum gaps.

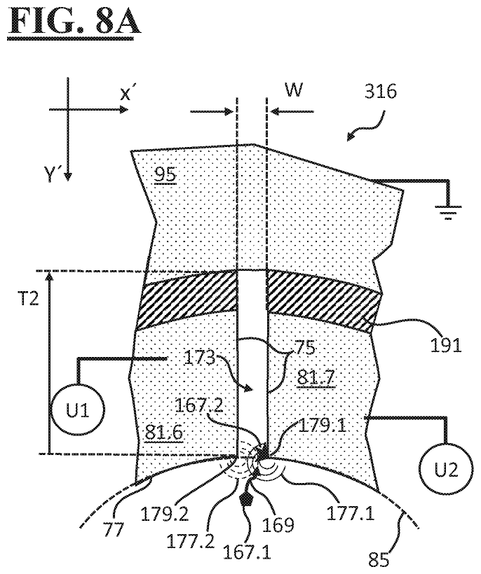

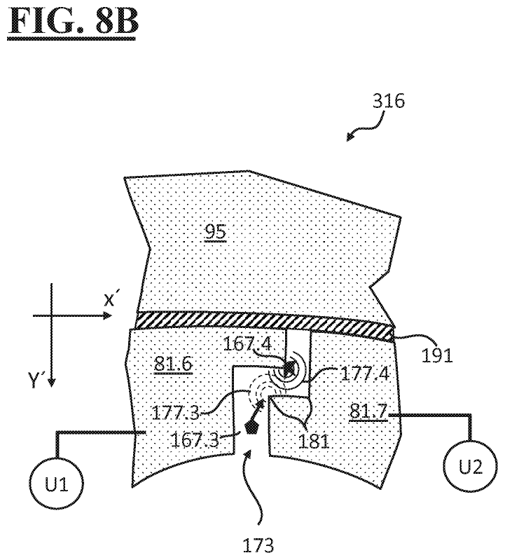

FIG. 8A gives a simplified illustration of the effect. A charged contamination particle or residual gas particle 167.1 is attracted and accelerated along path 169 by the large field gradients 177.1, 177.2 arising between the edge 179.1 of electrode 81.7 and edge 179.2 of electrode 81.6. The edges 179 are formed at the intersection of the side surfaces 75 of the vacuum gaps 173 and the inner surface 77 of an electrode 81 to the aperture 85. The large field gradients 177.1, 177.2 at the edges 179 are generated during use according to a voltage difference U2−U1 applied to the electrodes 81.6 and 81.7. The large field gradients 177.1, 177.2 are illustrated in simplified manner. A contamination particle 167.1 can stick to an edge 179.1. After accumulating several particles 167.2 sticking to the edge 179.1, the gap width W is effectively reduced, and a spark can be generated during use. A similar effect is expected for inner edges 181 within T-shaped or labyrinth-shaped vacuum gap 173 (see FIG. 8B). Contamination particles 167.3 within a vacuum gap 173 are accelerated by the high local field gradients at the inner edge 181 and can form accumulated regions of contamination particles 167.4 sticking at an inner edge or corner 181 to an electrode 81.6 or 81.7. Thereby, sparks or even shorts can arise during use.

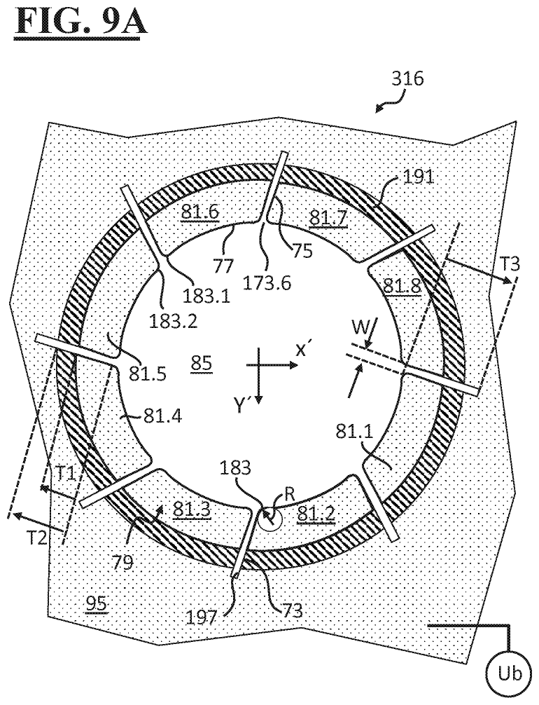

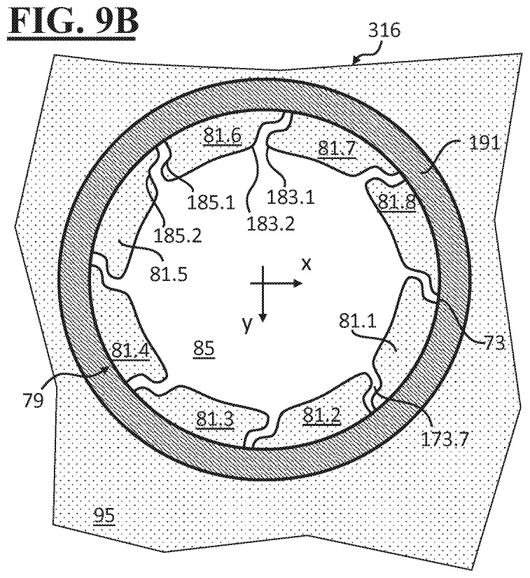

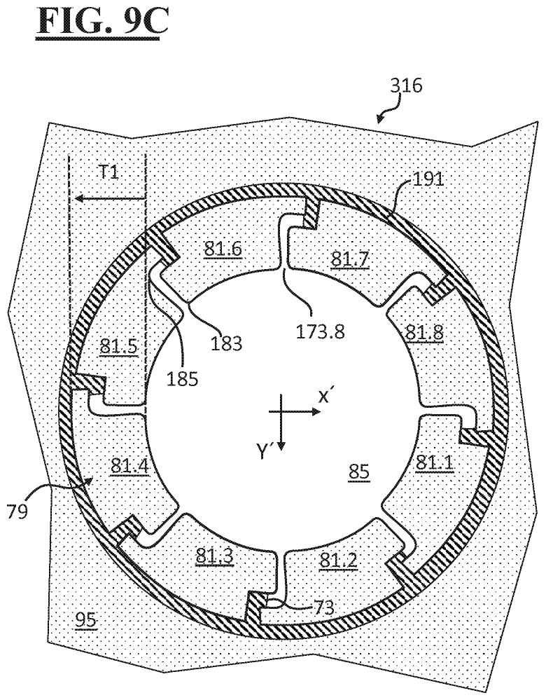

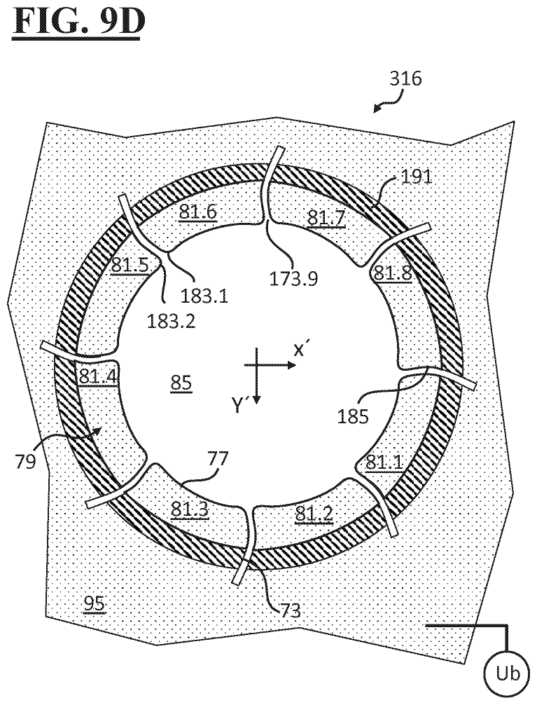

According to an embodiment, a multipole array element 316 therefore comprises at each aperture a plurality of electrodes with vacuum gaps 173.6 and without edges 181 or 179. For example, the intersections between two side surface segments 75 of a vacuum gap 173 and an inner surface 77 of an electrode 81 are rounded with radius R>=1 μm, for example R=2 μm, for example R=3 μm, or for example R=4 μm. Thereby, large field gradients 177 as illustrated in FIG. 8 are avoided. A first example is illustrated in FIG. 9A. Same reference numbers as in FIG. 7 are used and reference is made to the description above. Tilted deep vacuum gaps 173.6 are formed, such that a probability, that electrons reach isolating surface regions 73 is reduced. Furthermore, surface intersections of the electrodes formed at the vacuum gaps 173.6 are rounded to form rounded, cylindrical edge segments 183, 183.1 and 183.2. The rounded edge segments 183 are extending in propagation direction of an electron beamlet transmitting the aperture 85 (in the figures the z′-direction perpendicular to x′ and y′). Thereby, a risk of sticking contamination to the intersections of surfaces 75 of the vacuum gaps 173.6 with the inner side surfaces 77 of the apertures 85 is reduced and the occurrence of sparks during use is reduced. Thereby, a voltage range for driving the multipole element can be increased for example by more than 30%, for example to above 26V difference between adjacent electrodes 81 or even more, for example 30V, and a larger manipulation range is achieved without a risk of sparks.

FIG. 9b illustrates another example of a multipole-array element 316 with a plurality of electrodes 81.1 to 81.8 with vacuum gaps 173.7 and without sharp edges 181 or 179. Here, in addition to the rounded edges segments 183.1 and 183.2 at the inner surface of the aperture 85, each vacuum gap 173.7 comprises a rounded contour or S-shape with rounded inner surface segments 185.1 and 185.2. Thereby, the risk of sticking contamination inside the vacuum gaps 173.7 is reduced and a probability that electrons reach an isolating surface region 73 is further reduced.

In the example illustrated in FIG. 9C, rounded surface segments 185 and rounded edges 183 are provided at the entry of vacuum gaps 173.8 as well as within the vacuum gaps 173.8. The example further shows electrodes of increased volume, reaching a larger depth T1 compared to the solutions of FIG. 9A or 9b. Electrodes 81.1 to 81.8 may partly reach behind each other and isolating surfaces 73 can—with respect to an electron beam passing the aperture 85—be hidden behind adjacent electrodes 81.1 to 81.8.

FIG. 9D shows vacuum gaps 173.9 with a chevron shape of “c”-shape with rounded edges 185 within the vacuum gaps 173.9 and rounded edges 183 at the intersection of the vacuum gaps 173.9 with the inner surface 77 of the aperture 85. Compared to T-shaped or S-shaped of J-shaped vacuum gaps, evacuation of vacuum gaps 173.9 with rounded chevron or C-shape can be beneficial and can have reduced probability that electrons reach the surface 75 of isolating material 191.

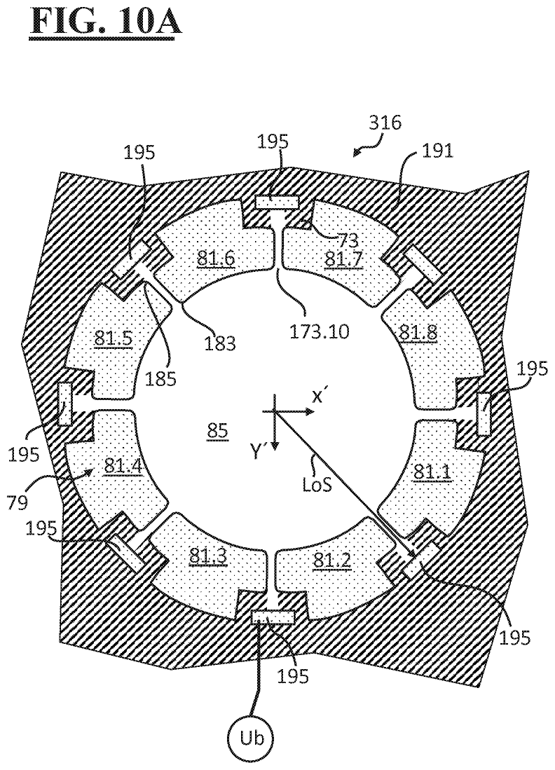

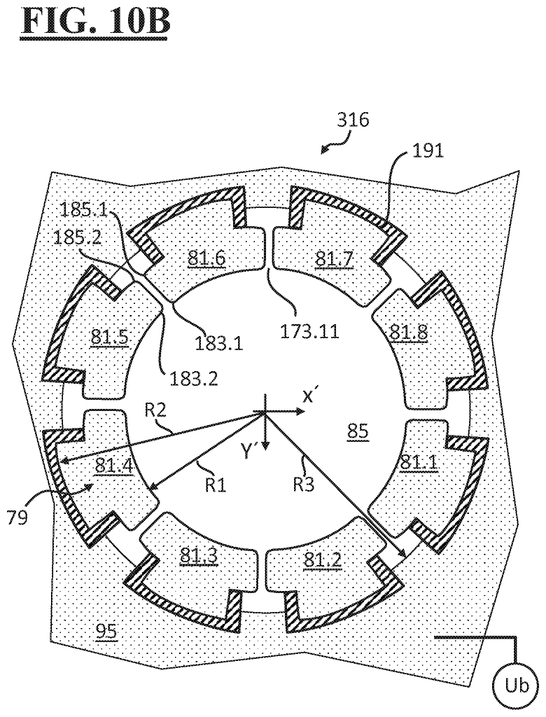

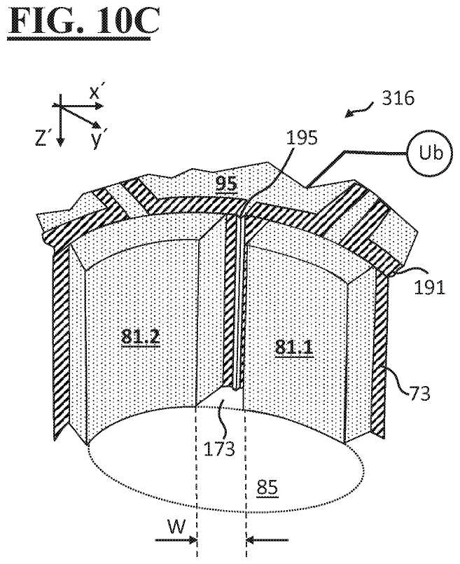

FIG. 10A shows another variation of vacuum gaps of a multipole electrode arrangement of a multipole array element 316. Again, sharp edges are avoided by rounded surface segments 183 and rounded edges 185. Here, additional electrodes 195 are embedded in isolating material 191 and vacuum gaps 173.10 are formed between adjacent electrodes 81.1 to 81.8 and additional electrodes 195. The open surface segments 73 of the isolating material 191 are hidden—from the transmitting electron beamlet 3 (not shown) through aperture 85—behind the electrodes 81.1 to 81.8. Inside a vacuum gap 137.10 along line-of-sight vector LoS, isolated electrodes 195 are provided, facing the line-of-sight-vector LoS within the vacuum gap 173.9. An individual voltage Ub can be provided to each of the electrodes 195, thereby contamination particles or any charged particle can be pushed out of the vacuum gaps 173.9 or attracted to the additional electrode (195).

FIG. 10B shows another example of a multipole-array element 316 with a plurality of electrodes 81.1 to 81.8 with t-shaped vacuum gaps 173.11 and without edges 181 or 179, but rounded surface segments 183 and 185. Here, electrodes 81.1 to 81.8 are isolated by isolating material 191, embedded within conducting material 95. In both examples, electrode 81.1 to 81.8 can be of larger volume with an outer electron radius R2 of electrodes exceeding an inner radius R3 of the conducting material 95.

FIG. 10C illustrates another example of a multipole array element 316. Thin electrodes 195 are provided within a vacuum gap 173 between two adjacent surfaces 73 of isolating material. The electrodes 195 are connected to a voltage supply. The electrodes 195 are arranged within the vacuum gaps 173 and can attract or repel charged particles, for example scattered electrons entering the vacuum gaps 173. Thereby, a surface charge of the open surfaces 73 or the isolating material 191 can be omitted. Instead of the thin electrode 195 it is also possible to provide a metal wire or wire grid on top of the open surface 73 of isolator material 191. Surface charges are thereby avoided and scattered charged particle within the vacuum gaps 173 are collected and guided to for example a positive voltage source Ub or ground level. In the examples of FIG. 10, generally the width W of the vacuum gap can be increased to about 4 μm or more and an evacuation of the vacuum gaps 173 can be improved.

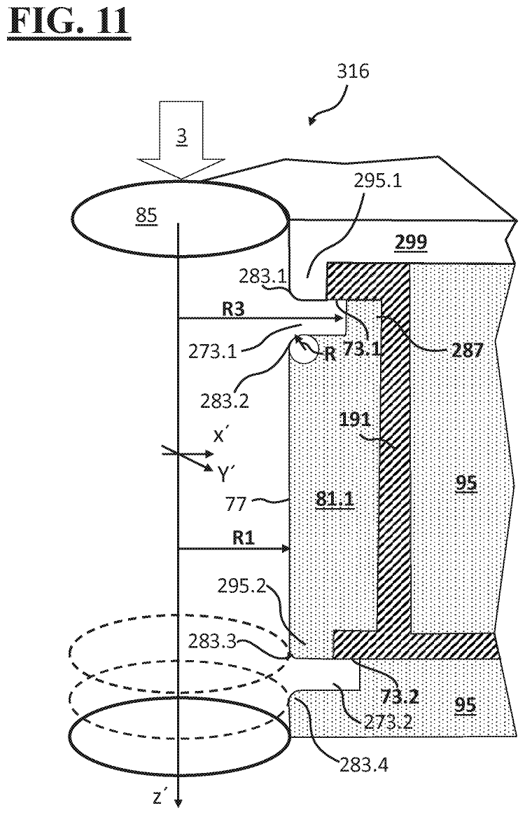

The vacuum gaps 173 for isolating adjacent electrodes 81 or multi-pole elements are extending in axial or z-direction, parallel to the propagation direction of the transmitting beamlets 3. Next to the axial vacuum gaps 173, the electrodes are further separated by radial vacuum gaps from conducting material of counter-electrodes upstream or downstream in propagating direction of the transmitting beamlets. FIG. 11 illustrates a cross section along a multipole array element 316 in x-z-direction at one aperture 85 of the plurality of apertures. A cross section through electrode 81.1 is illustrated. The electrode 81.1 is isolated from conducting material (for example doped silicon or poly-silicon) 95 by isolating material 191, which is for example silicon dioxide. Upstream of the electrode 81.1 in direction of the transmitting electron beamlet 3, a conducting cover layer 299 is provided, which is configured to absorb incident electrons. The conducting layer 299 is provided with a plunging extension 295.1 in direction of the propagating electron beamlet 3. The electrode 81.1 is provided with an extension or yoke 287 with the larger Radius R3 on the incident side of the electron beamlet 3. Between the plunging extension 295.1 and the yoke 287 of the electrode 81.1, a radial vacuum gap 273.1 of radius R3 is formed. The radial vacuum gap 273.1 is provided with an open surface section 73 of an isolating material 191. The open surface section 73 is hidden behind the plunging extension 295.1 of cover layer 299. Thereby, a probability that electrons may reach the open surface section 73 of the isolating material 191 is reduced. Furthermore, plunging extension 295.1 is provided with a rounded surface ring segment 283.1 with radius R, such that large local field gradients at the vacuum gap 273.1 are reduced. The (in viewing direction of FIG. 11) upper inner edge of the electrode 81.1 is further provided with a rounded, ring shaped surface segment 283.2 with radius R of about R=2 μm or 3 μm, such that large local field gradients are reduced. In a similar manner the second vacuum gap 273.2, downstream of the electrode 81.1 is configured. The plunging extension 295.2 is here provided at the electrode 81.1. Generally, plunging extensions 295.1 and 295.2 for covering an open surface 73.1 and 73.2 of an isolating material 191 are provided in direction of the transmitting beamlet 3 always at a conducting element upstream of a radial vacuum gap 273. Edges with the inner surface 77 of the aperture 85 are again rounded and form rounded shaped ring segments 283.3 and 283.3, such that large local field gradients are reduced.

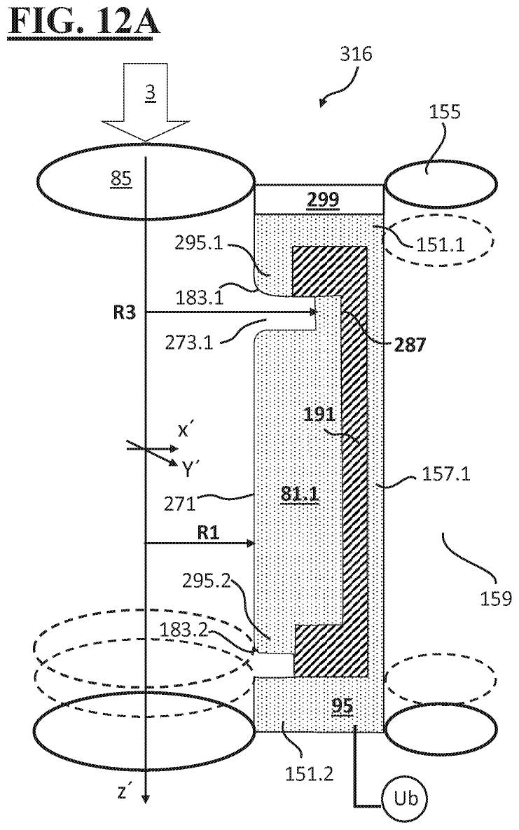

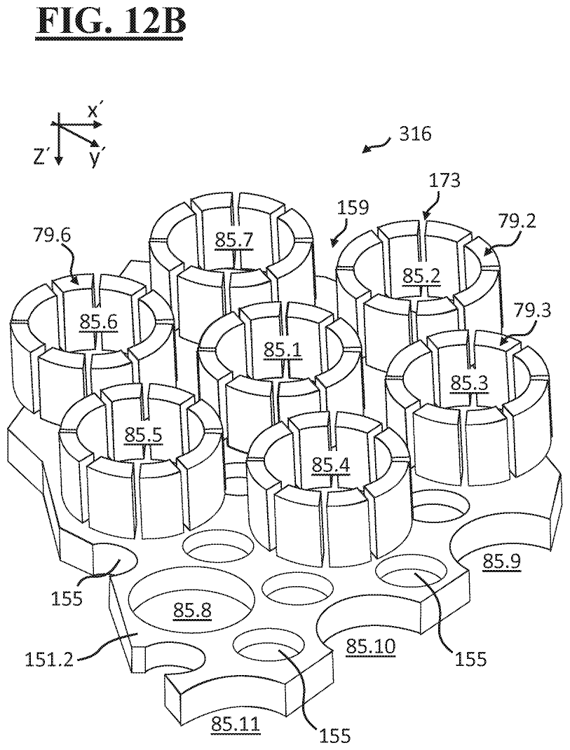

FIG. 12A illustrates another example of a multipole array element 316. Same reference numbers as in FIG. 11 are used and reference is also made to the description of FIG. 11. Here, the plurality of electrodes 81 are embedded between first and second outer layers 151.1 and 151.2. In addition to the apertures 85, a plurality of additional vacuum apertures 155 are provided. The electrodes 81 (81.1 in FIG. 12A) are isolated from outer layers 151.1 and 151.2 by isolating material 191 and embedded in conducting material 95, with forms a shielding electrode layer 157 behind each electrode 81, in FIG. 12A shielding layer 157.1 behind electrode 81.1, separated by isolating material 191. Between each electrode segment, isolation is provided by vacuum space 159. With the additional vacuum apertures 155 provided in the outer layers 151.1 and 151.2, a vacuum generation withing the vacuum gaps 173 between adjacent electrodes 81 can be improved. FIG. 12B shows a simplified perspective illustration with the lower or second outer layer 151.2 and the plurality of electrodes at each of the apertures 85 for the electron beamlets and the further vacuum apertures 155. The first outer layer 155.1 at the side of incidence of the electron beamlets is not shown, but comprises same apertures 85 and 155. Via apertures 155, the vacuum space 159 between electrodes is evacuated. Vacuum space 159 is connected to the vacuum gaps 173, and an evacuation of the narrow vacuum gaps 173 can be improved. According to this example, the plurality of electrodes 81 is connected to at least a first or second outer or cover layer 151.1 or 151.2 and isolated from first or second outer or cover layer 151.1 or 151.2 by an isolating material 191. Between the first and second layer 151.1 and 151.2, each electrode 81 is entirely enclosed by vacuum, formed by vacuum gaps 173, vacuum inside apertures 85 and vacuum space 159 behind each electrode 81. Each electrode 81 can further be provided with a shielding electrode layer 157. Shielding electrode layer 157 can be connected to first or second outer layer 151.1 and 151.2 or both.

According to an embodiment, a method of attracting or repelling of charged particles in or from a narrow vacuum gap 173, 273 between adjacent electrodes 81 of a multipole-element is provided. For example, during an evacuation or during use of a multi-beam charged particle beam system 1, a voltage Ub is provided to electrodes arranged within a vacuum gap 173, 273, thereby generating an either attracting or repelling force to charged particles within a vacuum gap 173, 273. Thereby, charged particles such as contamination particles can be removed from within a narrow vacuum gap, or can be accelerated deep into a narrow vacuum gap and collected at an electrode or pocket within the vacuum gap. Thereby, evacuation can be improved and the risk of sparks during use is reduced.

The disclosure can provide an improvement to a multipole array for a multi-beam system. At least one of an improvement regarding better evacuation, less contamination risk and increased manipulation range is achieved by at least one improvement mechanism comprising rounded edges within vacuum gaps, deep pockets formed in conducting material, and electrodes within vacuum gaps for generating repelling or attracting forces to charged particles.

The disclosure and the embodiments of the disclosure can be described by following clauses.

### Clause 1

A multi-pole array (316) for manipulating a plurality of primary charged particle beamlets (3), comprising:
a plurality of first apertures (85), each one for transmitting one of the plurality of primary charged particle beamlets (3),
at least a first electrode and a second electrode (81, 81.1, 81.2, 81.3, 81.4, 81.5, 81.6, 81.7, 81.8), arranged at each aperture (85) to form a multipole element (79) and connected to a control unit (830) for individual control of a primary charged particle beamlet (3), each electrode (81) having a radial thickness T1, the first and second electrodes (81, 81.1, 81.2, 81.3, 81.4, 81.5, 81.6, 81.7, 81.8) having an inner surface (77) within an aperture (85), and the at least first electrode and a second electrode (81, 81.1, 81.2, 81.3, 81.4, 81.5, 81.6, 81.7, 81.8) being embedded in a conducting material (95) and isolated from the conducting material (95) by ring segments of an insulating material (191) between the electrodes (81, 81.1, 81.2, 81.3, 81.4, 81.5, 81.6, 81.7, 81.8) and the conducting material (95),
a vacuum gap (173) with side surfaces (75) formed between the first and second electrode with width W and depth T3 and with an aspect ratio AR=T1/W, the depth T3 being larger than a depth T2 of the insulating material (191), thereby forming a pocket (197) in the conducting material (95).

### Clause 2

The multi-pole array (316) of clause 1, wherein the width W is less than 3 μm, for example 2 μm or 1.6 μm and the aspect ratio AR=T1/W is larger than 8:1, for example 10:1.

### Clause 3

The multi-pole array (316) of clause 1 or 2, wherein a tangent to a side surface (75) of the vacuum gap (173) is inclined with respect to a radius vector (187) to a center of a corresponding first aperture (85) by an angle J with J>15°, for example 20° or 30° or even 45°.

### Clause 4

The multi-pole array (316) according to any of the clauses 1 to 3, wherein an intersection between the inner surface (77) of the first electrode (81) and a side surface (75) of a vacuum gap (173) form at the intersection a rounded, cylindrical edge segment (183) with a radius R exceeding 1 μm, for example R=2 μm or R=3 μm, thereby avoiding large field gradients (177).

### Clause 5

The multi-pole array (316) according to any of the clauses 1 to 4, wherein the vacuum gap (173) comprises planar side surfaces (75).

### Clause 6

The multi-pole array (316) according to any of the clauses 1 to 4, wherein a side surface (75) of the vacuum gap (173) comprises a rounded surface segment (185) for avoiding large field gradients (177) within the vacuum gap (173).

### Clause 7

The multi-pole array (316) of clause 6, wherein a vacuum gap (173) has a cross section in shape of an “s” or a rounded chevron or “c”-shape.

### Clause 8

The multi-pole array (316) according to any of the clauses 1 to 7, further comprising a voltage supply for providing a voltage Ub to the conducting material (95).

### Clause 9

A multi-pole array (316) for manipulating a plurality of primary charged particle beamlets (3), comprising:
a plurality of first apertures (85), each one for transmitting one of the plurality of primary charged particle beamlets (3),
at least a first electrode and a second electrode (81, 81.1, 81.2, 81.3, 81.4, 81.5, 81.6, 81.7, 81.8), arranged at each aperture (85) and connected to a control unit (830) for individual control of a primary charged particle beamlets (3), the first and second electrodes (81, 81.1, 81.2, 81.3, 81.4, 81.5, 81.6, 81.7, 81.8) having an inner surface (77) within an aperture (85), and the at least first electrode and a second electrode (81, 81.1, 81.2, 81.3, 81.4, 81.5, 81.6, 81.7, 81.8) being embedded in an isolating material (191),
a vacuum gap (173) with side surfaces (75) formed between the first and second electrode,
an additional electrode (195) arranged inside the vacuum gap (173) in a direction of a line of sight (LoS) with a primary charged particle beamlet (3) transmitting a first aperture (85), the additional electrode (195) being connected to a voltage supply for providing voltage Ub for generating a repelling or attracting force to charged particles entering the vacuum gap (173).

### Clause 10

The multi-pole array (316) of clause 9, wherein the additional electrode (195) is formed a thin wire or wire grid.

### Clause 11

The multi-pole array (316) according to any of the clauses 1 to 10, further comprising a conducting cover layer (299) at a first side of incidence of the plurality of primary charged particles (3), the conducting cover layer (299) comprising a plunging extension (295.1) extending in propagation direction and covering the isolating material (191), and forming a first radial vacuum gap (273.1) with each electrode (81, 81.1, 81.2, 81.3, 81.4, 81.5, 81.6, 81.7, 81.8).

### Clause 12

The multi-pole array (316) according to any of the clauses 1 to 11, wherein each electrode (81, 81.1, 81.2, 81.3, 81.4, 81.5, 81.6, 81.7, 81.8) comprises a plunging extension (295.2) extending in propagation direction and covering the isolating material (191), and forming a second radial vacuum gap (273.2) with a conducting material (95) downstream of the electrodes (81, 81.1, 81.2, 81.3, 81.4, 81.5, 81.6, 81.7, 81.8).

### Clause 13

The multi-pole array (316) according to any of the clauses 11 or 12, wherein, at the first or second radial vacuum gap (273.2), at least one round shaped ring segment (283) is provided for avoiding large field gradients within a vacuum gap (273.1, 273.2).

### Clause 14

The multi-pole array (316) according to any of the clauses 1 to 13, further comprising a plurality of second or vacuum apertures (155), each of the vacuum apertures (155) connected to a vacuum gap (173) from the rear end opposite to an inner surface (77) of a first aperture (85).

### Clause 15

A multi-pole array (316) for manipulating a plurality of primary charged particle beamlets (3), comprising:
a plurality of first apertures (85), each one for transmitting one of the plurality of primary charged particle beamlets (3),
at least a first electrode and a second electrode (81, 81.1, 81.2, 81.3, 81.4, 81.5, 81.6, 81.7, 81.8), arranged at each aperture (85) and connected to a control unit (830) for individual control of a primary charged particle beamlets (3), the first and second electrodes (81, 81.1, 81.2, 81.3, 81.4, 81.5, 81.6, 81.7, 81.8) having an inner surface (77) within an aperture (85), and the at least first electrode and a second electrode (81, 81.1, 81.2, 81.3, 81.4, 81.5, 81.6, 81.7, 81.8) comprise a layer of isolating material (191) on a side opposite to the inner surface (77), the layer of isolating material (191) being covered by conducting material (95) connected to a voltage supply for providing a voltage Ub or ground level,
a vacuum gap (173) with side surfaces (75) formed between the first and second electrode,
a first outer layer (151.1), covering the electrodes (81) from a direction of the incident primary beamlets (3), comprising the plurality of first apertures (85), and further comprising a plurality of second or vacuum apertures (155) for evaporation of a vacuum space (159) between the electrodes (81, 81.1, 81.2, 81.3, 81.4, 81.5, 81.6, 81.7, 81.8) of different apertures (85, 85.1 to 85.11).

### Clause 16

The multi-pole array (316) according to any of the clauses 8 to 15, wherein the voltage supply is configured to provide a pulsed voltage Ub during evacuation for increased evacuation of a vacuum gap (173).

### Clause 17

The multi-pole array (316) according to any of the clauses 8 to 16, wherein the voltage supply is configured to provide a voltage Ub during operation of the multi-pole array (316).

### Clause 18

A multi-beam charged particle beam system (1), comprising at least a first multi-pole array (316, 306, 390) according to any of the clauses 1 to 17.

### Clause 19

The multi-beam charged particle beam system (1) according to clause 18, wherein the first multi-pole array (316, 306) is arranged within a multi-beam forming unit (305), configured for individually deflecting, focusing, or shaping during use at least one of a plurality of primary charged particle beamlets (3).

### Clause 20

The multi-beam charged particle beam system (1) according to clause 18, wherein the first multi-pole array (316, 390) is arranged near an intermediate image surface (321) for individually deflecting during use at least one of a plurality of primary charged particle beamlets (3).

### Clause 21

The multi-beam charged particle beam system (1) according to clause 19 or 20, further comprising a second multi-pole array (316, 306, 390).

### Clause 22

The multi-beam charged particle beam system (1) according to clause 21, wherein the first and second multi-pole array (316, 306) are configured for at least two functions selected from the functions of individually deflecting, individually focusing, and individually shaping during use at least one of a plurality of primary charged particle beamlets (3).

### Clause 23

The multi-beam charged particle beam system (1) according to clause 21, wherein the first and second multi-pole array (316, 306) are configured for at least a first deflection to adjust a position of a primary charged particle beamlet (3) at an image plane (101) and configured for at least a second deflection to adjust an angle of a primary charged particle beamlet (3) at an image plane (101).

### Clause 24

The multi-beam charged particle beam system (1) according to any of the clauses 18 to 23, further comprising a filter plate (304, 304.2) with the plurality of apertures (85) upstream of the multi-pole array (316, 306, 390), configured for generating during use a plurality of primary charged particle beamlets (3) from an incident charged particle beamlet (309).

### Clause 25

The multi-beam charged particle beam system (1) according to clause 24, wherein each of the plurality of apertures (85, 85.0, 85.11, 85.12, 85.22) of the filter plate (304, 304.2) have cross-sections of different size, shape or orientation.

The disclosure is however not limited to the clauses. It is understood that various combinations and modifications are possible.

A list of reference numbers is provided:
1 multi-beam charged-particle system
3 primary charged particle beamlets
5 primary charged particle beam spots
7 object or wafer
9 secondary charged particle beamlets
11 secondary charged-particle beam path
13 primary charged-particle beam path
15 secondary charged particle image spots
25 top surface
73 open surface regions
75 sidewall of vacuum gap
77 inner surface of an aperture
81 electrode or electrodes
82 global electrode
83 spacer
85 aperture
86 electrical wiring interconnections
89 center of an aperture
95 conducting material
99 absorber layer
100 object irradiation unit
101 object plane
102 objective lens
103 field lens group
105 optical axis
108 beam cross over
109 tilt angle
110 multi-beam raster scanner
111 plane 111 parallel to the image plane
113 far field distributions
116 multi-pole or multi-stigmator array
117 pupil distribution
151 outer layer
155 vacuum apertures
157 shielding layer
159 vacuum space between electrodes
167 contamination or residual gas particle
173 vacuum gap or recession
177 large field gradient
179 edge between side surface and inner aperture surface
181 edges within vacuum gap
183 rounded edge segment
185 rounded inner surface segments
191 isolating material
195 additional electrodes
197 pockets
200 detection unit
205 Projection system
206 electrostatic lens
207 image sensor
208 electrostatic or magnetic lens
209 electrostatic or magnetic lens
210 electrostatic or magnetic lens
212 second cross over
214 aperture
216 active element
218 deflection unit
220 multi-aperture corrector
222 second collective raster scanner
273 radial vacuum gap
283 rounded surface ring
287 yoke
295 plunging extension
299 conducting cover layer
300 charged-particle multi-beam generator
301 source of primary charged particles
302 deflector
303 collimating lens
304 filter plate
305 multi-beam generating unit
306 multi-aperture plates
308 field lens
309 primary charged particle beam
311 plurality of focus points
316 first aperture plate
321 intermediate image surface
333 support zone
335 inner zone
390 beam steering multi aperture plate
400 beam splitter unit
420 magnetic correction element
500 stage
503 sample voltage supply
800 control unit
820 scanning and imaging control unit
830 primary beamlet control module

1. A multi-pole array configured to manipulate a plurality of primary charged particle beamlets, the multi-pole array comprising:
a plurality of first apertures, each aperture configured to transmit one of the plurality of primary charged particle beamlets;
at each aperture, first and second electrodes configured to define a multipole element and configured to be connected to a control unit to individually control a primary charged particle beamlet,
wherein:
for each of the first and second electrodes:
the electrode has a radial thickness;
the electrode has an inner surface within the aperture;
the electrode is embedded in a conducting material;
the electrode is isolated from the conducting material by ring segments of an insulating material between the electrode and the conducting material; and
a vacuum gap with side surfaces is between the first and second electrodes;
the vacuum gap has a width;
the vacuum gap has a depth;
the vacuum gap has an aspect ratio equal to the radial thickness of the first and second electrodes divided by the width of the vacuum gap; and
the depth of the vacuum gap is greater than a depth of the insulating material, thereby defining a pocket in the conducting material.

2. The multi-pole array of claim 1, wherein the width of the vacuum gap is less than three microns, and the aspect ratio is greater than 8:1.

3. The multi-pole array of claim 1, wherein, for each aperture, a tangent to a side surface of the vacuum gap is inclined with respect to a radius vector to a center of the aperture by more than 15°.

4. The multi-pole array of claim 1, wherein, for each aperture, an intersection between the inner surface of the first electrode and a side surface of the vacuum gap is a rounded, cylindrical edge segment with a radius of more than one micron.

5. The multi-pole array of claim 1, wherein, for each aperture, the vacuum gap comprises planar side surfaces.

6. The multi-pole array of claim 1, wherein, for each aperture, the side surface of the vacuum gap comprises a rounded surface segment.

7. The multi-pole array of claim 6, wherein, for each aperture, the vacuum gap has an s-shaped cross section, a rounded chevron cross section, or a c-shaped cross section.

8. The multi-pole array of claim 1, further comprising a voltage supply configured to provide a voltage to the conducting material.

9. The multi-pole array of claim 8, wherein the voltage supply is configured to provide a pulsed voltage during evacuation for increased evacuation of a vacuum gap.

10. The multi-pole array of claim 8, wherein the voltage supply is configured to provide a voltage during operation of the multi-pole array.

11. The multi-pole array of claim 1, further comprising a conducting cover layer at a first side of incidence of the plurality of primary charged particles, wherein the conducting cover layer comprises a plunging extension extending in propagation direction and covering the isolating material and defining a first radial vacuum gap with each electrode.

12. The multi-pole array of claim 11, wherein each electrode comprises a plunging extension extending in propagation direction, covering the isolating material and defining a second radial vacuum gap with a conducting material downstream of the electrodes.

13. The multi-pole array of claim 12, wherein, at the first or second radial vacuum gap, at least one round shaped ring segment is provided to avoid large field gradients within a vacuum gap.

14. The multi-pole array of claim 11, further comprising a plurality of second or vacuum apertures, wherein each vacuum aperture is configured to be connected to a vacuum gap from a rear end opposite to an inner surface of a first aperture.

15. A system, comprising:
the multi-pole array of claim 1,
wherein the system is a multi-beam charged particle system.

16. The system of claim 15, further comprising a multi-beam forming unit configured to individually deflect, focus, or shape at least one of a plurality of primary charged particle beamlets, wherein the multi-pole array is within the multi-beam forming unit.

17. The system of claim 15, wherein the first multi-pole array is near an intermediate image surface to individually deflect at least one of a plurality of primary charged particle beamlets.

18. (canceled)

19. (canceled)

20. A system, comprising:
first and second the multi-pole arrays according to claim 1,
wherein the system is a multi-beam charged particle system.

21. (canceled)

22. (canceled)

23. (canceled)

24. (canceled)

25. A multi-pole array configured to manipulate a plurality of primary charged particle beamlets, the multi-pole array comprising:
a plurality of first apertures, each aperture configured to transmit one of the plurality of primary charged particle beamlets;
at each aperture, first and second electrodes configured be connected to a control unit to individually control a primary charged particle beamlet,
wherein:
for each of the first and second electrodes:
the electrode has an inner surface within the aperture;
the electrode is embedded in a conducting material;
a vacuum gap with side surfaces is between the first and second electrodes;
an additional electrode is within the vacuum gap in a direction of a line of sight with the primary charged particle beamlet to be transmitted by the aperture;
the additional electrode configured to be connected to a voltage supply to provide a voltage to generate a repelling or attracting force to charged particles entering the vacuum gap.

26.-42. (canceled)

43. A multi-pole array configured to manipulate a plurality of primary charged particle
beamlets, the multi-pole array comprising:
a plurality of apertures, each aperture configured to transmit one of the plurality of primary charged particle beamlets;
at each aperture, first and second electrodes configured be connected to a control unit to individually control a primary charged particle beamlet,
wherein:
for each of the first and second electrodes:
the electrode has an inner surface within the aperture;
the electrode comprises a layer of isolating material on a side opposite the inner surface of the electrode;
the layer of the isolating material is covered by a conducting material configured to be connected to a voltage supply to provide a voltage or ground level;
a vacuum gap with side surfaces is between the first and second electrodes;
a first outer layer covers the first and second electrodes from a direction of the incident primary beamlets;
a plurality of second or vacuum apertures is between the first and second electrodes or is between different apertures of the plurality of the apertures.

44.-55. (canceled)
